(19) United States
(12) Patent Application Publication
(10) Pub. No.: US 2015/0259158 A1
(43) Pub. Date: Sep. 17, 2015

(54) CONTINUOUS ENTRANCE/EXIT PORT FOR CHAMBERS OF DIFFERENT PRESSURE AND/OR GASES

(71) Applicant: John Swyers, Mansfield, MA (US)

(72) Inventor: John Swyers, Mansfield, MA (US)

(21) Appl. No.: 14/206,057

(22) Filed: Mar. 12, 2014

(51) Int. Cl. B65G 49/00; H01J 37/32; B08B 13/00; F27B 9/04; B65H 20/00

(52) U.S. Cl. CPC B65G 49/00; F27B 9/045; B65H 20/00; B08B 13/00; H01J 37/32733

(57) ABSTRACT

An improved port, for chambers of different pressures or gases, that permits continuous material to enter and exit a processing chamber with greatly reduced leakage between adjacent chambers or the atmosphere. The dimensions of the gap between the material and port and the length of the port will reduce air leakage into the processing chambers due to the flow characteristics of gases. The elongated port will improve conditions in chambers that utilize reduced pressure or controlled atmosphere to isolate the product and process from the degrading effects caused by air in the process zone. Thus, the reduced air leakage will improve product quality and can also reduce equipment costs required in building and maintaining the machine.

### BACKGROUND OF THE INVENTION:

The present invention relates to ports on a treatment machine where a material enters and exits the machine in one continuous strip or on a belt that carries the material or parts through the machine. In particular the present invention seeks to decrease the gas leakage of ports so that less air leaks in and less surrounding gases can leak between the chambers. This will improve process conditions and the final product.

After the mid-twentieth century various manufacturing processes or industries evolved so that technical people realized that removing the air that surrounds the product under treatment would improve the end results. In modern material processing it is beneficial to control the amount and the type of gases surrounding the material being processed. Common examples are the heating of metals in chambers wherein the air, or specifically oxygen, is controlled to reduce the corrosion or oxidation of the metal. Polymers and other materials are processed in similar arrangements. In some machines another gas, called a blanket gas, is substituted for air. In other machines the chamber pressure is greatly reduced below atmospheric pressure, i.e. a vacuum is used, as another method of reducing or eliminating the air from reaching the material in treatment. To achieve lower costs, improve handling and other reasons, the material under treatment can be treated in continuous strip form or placed on a continuous flexible belt.

Often the method or technique used to control leakage of air is not as successful as desired. If processing can be done in closed chambers the seals are much more successful than in “pass through” or “air to air” or continuous belt chamber designs. A closed chamber can use a seal based on compression or physical tightness. An “air to air” machine, with vacuum inner chambers or controlled atmosphere chambers, traditionally uses one of 3 types of ports to block inrushing air-slits, rollers, or sliding blocks. Thus the purpose of the port is to isolate the chamber from undesirable gases. A slit port is a thin piece of material that surrounds the continuous belt or strip. Rectangular slit ports or circular orifice slits are also used in controlled atmosphere systems where the inner chambers or zones often utilize inert gases. Ambient conditions prevail at the entrance and also at the exit of the machine.

### FIG. 1A Slit Port—Prior Art

10 is the material under treatment, moving from left to right. Chamber details not shown
20 is the upper and lower walls of machine chamber
30 is the upper and lower members of the slit port, attached to the wall of the chamber
40 is the gap between the material and the slit pieces
A roller design is also used such that the roller rides on the material under treatment and blocks air from entering.
   FIG. 1B Roller Port—Prior Art: Side view of typical roller port with 2 chambers and the inner treatment chamber (exit not shown)
10 is the material under treatment, moving from left to right
20 two chambers of the machine
20′ inner treatment chamber
30 rollers contacting the material under treatment
40 is the gap between the material and the rollers
NOT shown-the gaps between the roller air guard on sides and opposite the material contact point
The sliding block port is in direct contact with the continuous material. The block slides on the continuous material as it enters and exits the machine. However, the friction and wear of the block must be managed very carefully in production environments.
   FIG. 1C Sliding Block Port—Prior Art: Side view of the main components
10 is the material under treatment, moving from left to right
20 is the upper and lower walls of machine chamber
30 is the upper and lower members of the sliding block port, riding on the material under treatment
40 the gap is between the material under treatment and the block
50 is the adjustable tensioning member attached to the sliding block

These types of ports are used on continuous belt ovens and furnaces, various treatment systems for wire or thread, and strip welding machines employing electron beam heating equipment.

FIG. 2: Typical Continuous Treatment System—Prior Art: Side View with slit ports
10 is the material under treatment, moving from left to right
20 is the upper and lower walls of each chamber of the machine
30 is the ports at the entrance and exit of each chamber of the machine
40 is the gap between the material and the port at each chamber of the machine
Ambient conditions prevail before and after the chambers. In many machines a plurality of chambers are required to achieve the desired treatment conditions. Each chamber usually has a different pressure or controlled atmosphere.
Most of these machines usually treat metals, polymers, woven or paper webs but they are not limited to any material. Usually the port design is the same for the entrance side and the exit side of the machine. The problem is some air always leaks through the gap between the slit and the continuous material causing the process to degrade along with product quality. By keeping the gap between the material (work in treatment) and the slit itself as small as possible, the air rushing into the treatment chambers will be reduced as much as possible. To overcome these problems multiple chambers with slits are used to limit and control the air leaking into the main treatment area. Thus, the slit or orifice is a simplistic and obvious approach to the problem of gas leakage.

What is needed is a continuous entrance-exit port that will greatly reduce the amount of ambient air that “leaks” into the inner chambers. This new port design should be applicable to both machine types-reduced or higher pressure atmospheres and controlled atmosphere systems.

### SUMMARY OF THE INVENTION:

The theoretical basis of this invention is to make the leak gas go through a long path length instead of an orifice type of air block between chambers. The new design—an elongated port with the same cross section as a slit or orifice—relies on the gas conductance characteristics so that the inrushing air is held back in a slightly different manner than the traditional slit port, roller + slit combinations, or sliding block. At first glance the elongated port may seem like a counterintuitive approach but it is based on the formulas that define conductance for flow due to pressure difference and for gas diffusion at atmospheric pressure. The length of the rectangular port and the gap will govern the amount of air that can leak into the chamber.

The advantage of less air leakage is 1. in low pressure machines—better vacuum or smaller vacuum pumps or faster material processing speeds through the machine and a possible elimination (reduction) of the number of chambers required and 2. in controlled atmosphere systems—less processing gas required and better temperature control.

The formulas from physical chemistry define conductance (with respect to these ports) as the resistance of gas to flow. Gas conductance depends on the shape and length of the path in which the gas is flowing as well as many characteristics of the gas itself. In summary, short ports have high conductance, elongated ports have much lower conductance. In all industrial applications slit designs have the highest conductance and therefore leak the greatest amount of air.

### DRAWINGS AND BRIEF DESCRIPTION OF THE DRAWINGS:

In all the drawings the following identifying numbers and descriptions will apply :

10 material under treatment

20 sidewall of the chambers

30 port, a restriction to block air flow

40 gap between material under treatment and port

FIGS. 1a, 1b, 1c: Common ports-slit, rollers, and sliding block

FIG. 1A Slit Port—Prior Art:

Side view of material under process and the slit and the gap between material and slit

FIG. 1B Prior Art Roller Port:

FIG. 1C Prior Art Sliding Block Port

FIG. 2: Typical Continuous Treatment System: Side View with slit ports

FIG. 3a Elongated port: front view from outside of chamber

10 is the material under treatment, moving into the page

20 is the chamber wall

30 is the upper and lower members of the elongated port, attached to the chamber wall

40 is the gap between the material and the elongated port members

FIG. 3b Elongated port: side view

10 is the material under treatment, moving from left to right

20 is the upper and lower members of the chamber wall

30 is the upper and lower members of the elongated port, attached to the chamber wall

40 is the gap between the material and the elongated port members

FIG. 3c Elongated port: oblique view

10 is the material under treatment, moving into the paper

20 chamber walls

30 is the upper and lower members of the elongated port

40 is the gap between the material and the elongated port members

This version will accommodate some left-right movement of the continuous material without allowing air to enter if the material shifts.

FIG. 3d Elongated port: isometric view

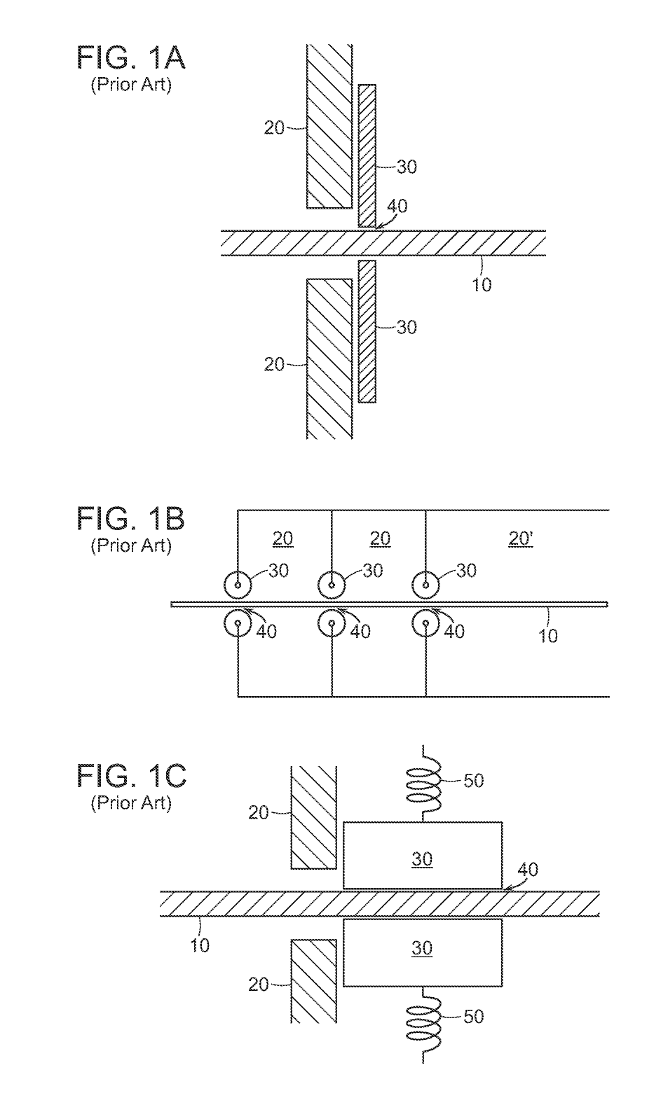

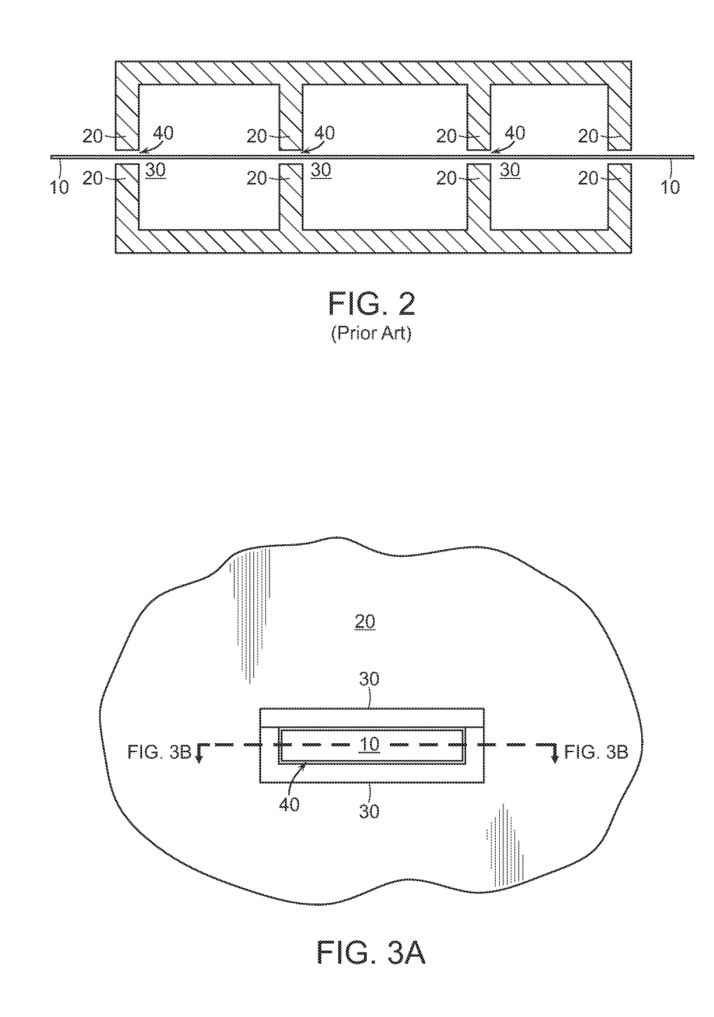

10 is the material under treatment, moving into the paper

20 chamber walls, not shown

30 is the upper and lower members of the elongated port

40 is the gap between the material and the elongated port members

This version will accommodate some left-right movement of the continuous material without allowing air to enter if the material shifts.

### FLOW DIAGRAMS ARE ILLUSTRATED IN FIG. 4:

1. Flow Diagram—chambers with pressure different than atmospheric
Obtain cross sectional shape of continuous material passing through the treatment chambers
Determine best practical length of the elongated port
Determine the smallest gap space between the elongated port and material
Determine best means of leak free attachment to mount the elongated port on the machine
Make and install the elongated port on the machine based on the above measurements
Repeat the above steps for each chamber on machine and install elongated ports on each chamber

2. Flow Diagram—chambers with belts and pressure close to atmospheric and with controlled gas compositions
Obtain cross sectional shape of continuous material, including belt and parts, passing through the treatment chambers
Determine best practical length of the elongated port
Determine the smallest gap space between the elongated port and all materials moving through the chambers
Determine best means of leak free attachment to mount the elongated port on the machine
Make and install the elongated port on the machine based on the above measurements
Repeat the above steps for each chamber on machine and install elongated ports on each chamber

### THE FOLLOWING TERMS USED HEREIN ARE DEFINED AS FOLLOWS

Belt—strands of metal, fiber or polymer interwoven to form a flexible support that has desired characteristics such as heat or chemical resistance. In industrial machines, the belt functions as an endless loop to carry parts or pieces into and out of a treatment zone such as an oven, welding box, or plasma chamber.
Gas flow—the movement of a volume of gas per unit of time, i.e. cubic meters per minute; if there is a pressure difference in a tunnel or tube gas will flow towards the lowest pressure
Port on a chamber—a hole or passageway in the wall of a chamber thru which a material can enter or exit
Pressure units—force per unit area; Pascal—Pa, the metric pressure unit used in literature and metric countries; not common in North American locations ; One atmosphere=101,000 Pa ; inches of water-H2O-a common unit used in North American for pressure close to atmospheric
Diffusion flow—random mixing of individual gas molecules due to temperature differences
Dynamic flow—gas movement due to pressure differences; 3 types of flow describe changes in characteristics of gases as the pressure increases or decreases
   a. molecular flow—as molecules bouncing off the walls of the container and not other molecules, occurs at low pressure
   b. viscous flow—near atmospheric pressure; gas molecules acting en mass, bouncing off each other
   c. laminar—a transition pressure between molecular and viscous flow
Plasma—a gas in an energetic state with electrically charged parts, i.e. ions, electrons, & atoms,
Controlled atmosphere—also called a blanket gas or isolating gas, a gas that surrounds material under treatment in chambers that exclude atmospheric air; used to create desired properties or inhibit faults in material under treatment.
Gas Conductance-volume of gas per time unit due to a pressure difference
Treatment—in industrial processes, a change to a part that creates desired characteristics in the part, such heat treatment for stronger metals, brazing and reflow solder to join parts, plasma cleaning of surfaces at the atomic level, optical curing (laser, I R, U V, etc.) of coating on webs, i.e. paper, woven, plastic.

### DETAILED DESCRIPTION

In one embodiment, obtain the cross section dimensions of the continuous material to be treated. Make an elongated port by constructing a long tube or rectangular structure with the shape of the cross section so that the elongated port will form a tunnel and surround the material. The internal dimensions of the elongated port must be slightly larger than the cross section dimensions of the continuous material under treatment to avoid binding and interference. The elongated port must be long enough to lower the air leakage to the level the machine operator desires. The elongated port should be as long as practical and economical for operational conveniences. In many cases the length will be more than 50 times greater than the gap dimensions. Attach the elongated port to the treatment machine in a leak free manner. In a similar manner attach an elongated port on each chamber the continuous material passes through. Different elongated ports on different chambers can have different lengths and different leak free attachment means according to the machine operators convenience. Direct the continuous material through each elongated port on each chamber and until it exits the machine. This completes the installation of the elongated ports on the machine and passing the continuous material through the machine. The machine should be ready to operate.

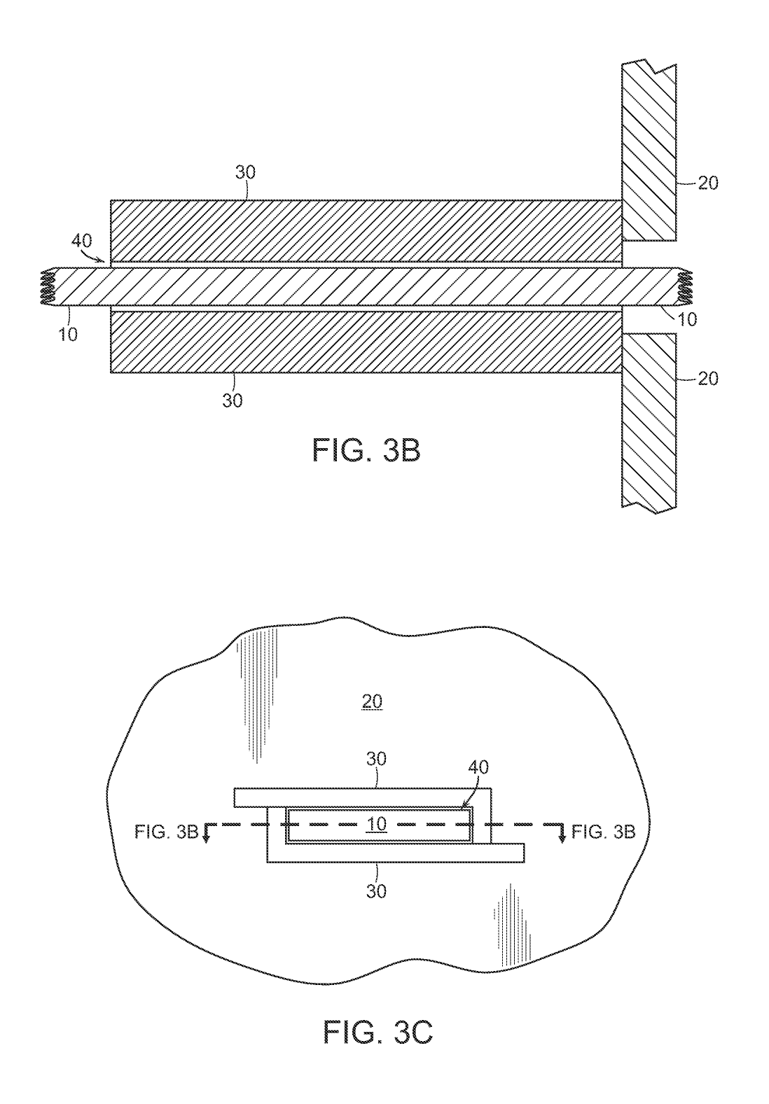

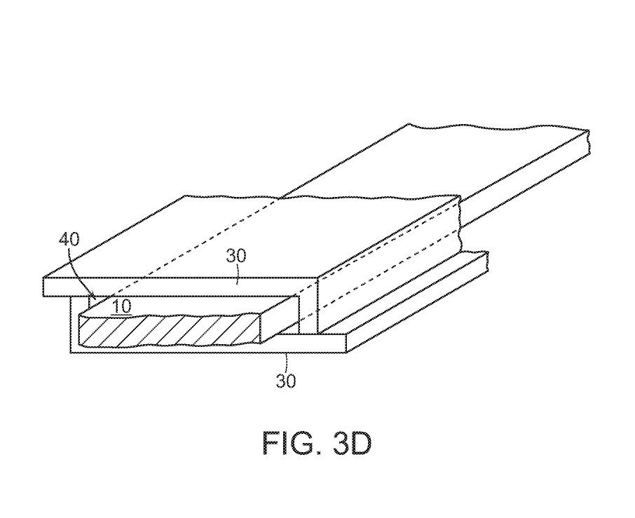

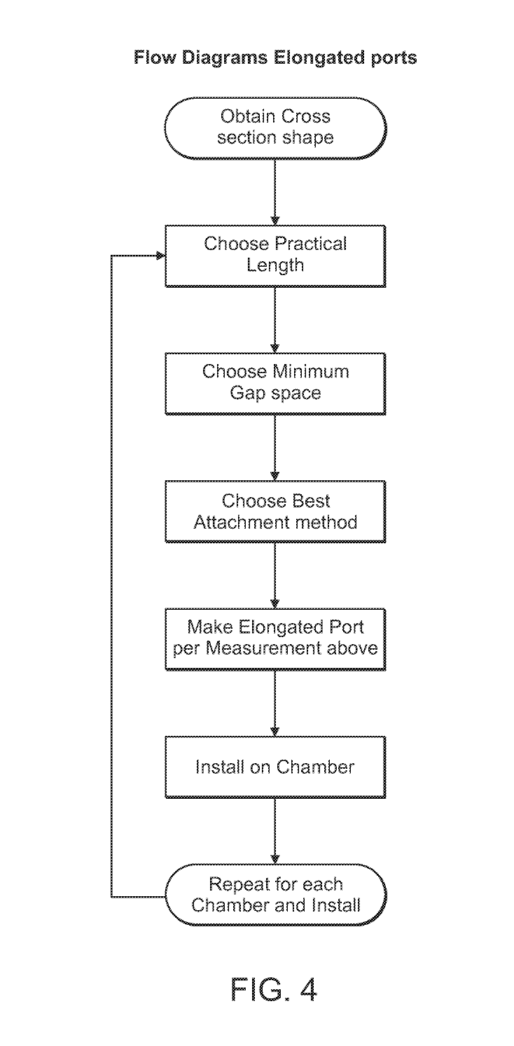

In another embodiment the elongated port can be constructed in a plurality of parts lengthwise. For example, by making the elongated port in two parts lengthwise it will be easier to change the continuous material or to remove the elongated port from the machine. Examples of this type of port are shown in FIGS. 3A, 3C and 3D. As shown in FIGS. 3C and 3D, these elongated ports will accommodate lateral movement in the continuous material as it passes through the machine. They are installed as described above. FIG. 3B illustrates the length of the port and the gap between the material and the port.

In another embodiment the elongated port can be constructed to surround a continuous flexible belt that carries parts through a plurality of chambers for treatment based on heat, chemical, plasma, optical, or other processes. In many cases, the length will be more than 10 times greater than the gap dimensions. The figures are the same with the addition of the parts placed on the belt. In some applications the elongated port can be made adjustable because the height of the parts will change according to different parts in the manufacturing plan. The machines with a belt design have fixtures so that an endless loop is formed by the belt.

The successful operation of the elongated port depends on the combination of a small gap and a long path length for the leaking gas. This will decrease the conductance per known formulas in various text books of Physical Chemistry and Vacuum sciences. The traditional slit is a two dimensional port with a high conductance. By adding a long path for the leaking gas to travel through the conductance is reduced. By adding more length to the port the conductance will be reduced accordingly. The combination of “small gap and a long path length” must reduce the flow enough so that the gas molecules travel according to the molecular flow formulas. Because the elongated port has both a very small gap and a long length for the leakage gas to pass through, the gas will be held back much more effectively than in the slit or roller ports. The conductance, and therefore gas leakage, from ambient conditions at the entrance or exit chamber and between adjacent chambers is minimized due to the flow characteristics of the elongated port. Each machine operator must decide the practical limits of the elongated port length and the smallest gap that yield adequate and acceptable performance.

Each machine user will decide on the best practical limits of the elongated port so that each installation is profitable. For example the length cannot be so long that it is cumbersome; the gap cannot be so small that binding and interference cause disruptions in production. The method of leak free attachment must be convenient and complementary to each machine. At least one embodiment of these versions will accommodate some left-right movement of the continuous material without allowing air to enter if the material shifts.
Turning now to the figures, the following figures show varying embodiments of the present invention:

FIG. 3a provides a front view from outside of chamber on which the elongated port is mounted. The material under treatment 10, is shown moving into the page, through an opening in chamber wall 20. The upper and lower members of the elongated port 30 are attached to the chamber wall. 40 is the gap between the material and the elongated port members.

FIG. 3B looks at the elongated port from the side, with the material under treatment 10 moving from left to right and into an opening in the chamber wall 20. The upper and lower members of the elongated port 30 are attached to the chamber wall. 40 is the gap between the material and the elongated port members.

In FIG. 3C we see a variation of the elongated port that will tolerate some movement in the material under treatment 10. If the material experiences a brief horizontally shift (left to right and right to left) any gas leaking will be minimized since the vertical part of the port will not be opened. FIG. 3C is a front view showing the material under treatment 10 moving into the paper through an opening in the chamber wall 20. The two parts of the elongated port 30 are attached to the chamber wall and the gap is 40.

FIG. 3D is an oblique view the FIG. 3C variation with the material under treatment 10 moving left to right and into the paper. The chamber wall is not shown. The two parts of the elongated port 30 are attached to the chamber wall and the gap is 40.

### CONCLUSIONS, RAMIFICATIONS AND SCOPE

The above descriptions illustrate the simplistic nature of the elongated port. The main benefits are decreased atmospheric gases leaking into and between chambers and ease of maintenance as well as reduced equipment to achieve the better results. The actual application of the elongated port may be complicated due to the construction of each machine on which the elongated port is applied. The elongated port will reduce the gas flow between chambers and from the atmosphere without additional vacuum pumps or pressure controlling devices. For isolation chambers and blanket gases, the elongated port will reduce the amount of gas needed to reduce diffusion gases from entering or leaving the chamber where the elongated port is installed.
The embodiments described above emphasize the basic characteristics that must be achieved in each elongated port for successful operation. A number of variations are possible to anyone reasonably skilled in the art.

1. An apparatus comprising;
a structure to form a tunnel to surround continuous material passing through a plurality of chambers;
said structure having a predetermined length and a predetermined gap to allow passage of said material, without restrictive contact or binding, to reduce a gas flow when said structure is positioned on at least one of the plurality of chambers; and
each of said plurality of chambers having a plurality of gas pressures.

2. The apparatus as in claim 1 such that said predetermined length of said structure must be more than 50 times greater than said predetermined gap dimension between the continuous material and said structure.

3. The apparatus as in claim 1 wherein at least one of the plurality of chambers is below 50,671 Pa absolute pressure.

4. The apparatus as in claim 1 wherein at least one of the plurality of chambers is above atmospheric pressure by 250 Pa.

5. The apparatus as in claim 1 wherein at least one of the plurality of chambers contains at least one of a plurality of gases different than air.

6. The apparatus as in claim 1 wherein at least one of the plurality of chambers contains heating devices configured to join a plurality of sections of said continuous material to form a singular continuous strip.

7. The apparatus as in claim 1 wherein at least one of the plurality of chambers contains Electron Beam heating devices configured to join a plurality of sections of said continuous material to form a singular continuous strip.

8. The apparatus as in claim 1 wherein said continuous material is woven.

9. The apparatus as in claim 1 wherein at least one chamber contains plasma generating equipment for purposes of modifying the surface structure of the continuous material.

10. An apparatus comprising;
a structure to form a tunnel to surround a continuous flexible belt carrying parts for treatment passing through at least one chamber;
said structure having a predetermined length and width and a predetermined gap to allow passage of said belt and parts, without restrictive contact or binding, to reduce a gas flow when said structure is positioned on at least one chamber; and
each of said at least one chamber having a plurality of pressures different than atmospheric pressure.

11. The apparatus as in claim 10 wherein the length of said structure must be more than 10 times greater than the gap dimension between the continuous flexible belt and parts and said structure.

12. The apparatus as in claim 10 wherein the pressure in at least one chamber is greater than 250 Pa above atmospheric pressure.

13. The apparatus as in claim 10 wherein at least one chamber contains a gas different than air.

14. The apparatus as in claim 10 wherein at least one chamber contains heating devices to raise the temperature above ambient of said parts on said continuous flexible belt.
